(19) United States
(12) Patent Application Publication
(10) Pub. No.: US 2014/0117524 A1
(43) Pub. Date: May 1, 2014

(54) POWER SEMICONDUCTOR MODULE AND MANUFACTURING METHOD THEREOF

(71) Applicant: SAMSUNG ELECTRO-MECHANICS CO., LTD., Suwon (KR)

(72) Inventors: Kwang Soo KIM, Suwon (KR); Young Ho SOHN, Suwon (KR); Bum Seok SUH, Suwon (KR); Min Gyu PARK, Suwon (KR); Young Ki LEE, Suwon (KR)

(73) Assignee: SAMSUNG ELECTRO-MECHANICS CO., LTD., Suwon (KR)

(21) Appl. No.: 13/735,603

(22) Filed: Jan. 7, 2013

(30) Foreign Application Priority Data
Oct. 30, 2012 (KR) 10-2012-0121229

(51) Int. Cl. H01L 23/00

(52) U.S. Cl. CPC H01L 24/25; H01L 24/82
USPC 257/676; 438/107

(57) ABSTRACT

There are provided a power semiconductor module and a manufacturing method thereof, the power semiconductor module including: a lead frame; a base substrate including a circuit wiring formed on an insulating layer thereof; a plurality of power semiconductor devices disposed to contact the circuit wiring; and a multilayer substrate formed by stacking a plurality of substrates and electrically connecting the power semiconductor devices and the lead frame to one another using a connection line formed therein and having conductivity.

### CROSS-REFERENCE TO RELATED APPLICATIONS

This application claims the priority of Korean Patent Application No. 10-2012-0121229 filed on Oct. 30, 2012, in the Korean Intellectual Property Office, the disclosure of which is incorporated herein by reference.

### BACKGROUND OF THE INVENTION

1. Field of the Invention

The present invention relates to a power semiconductor module capable of being manufactured without performing separate wire bonding by using a multilayer substrate having a conductive line provided therein, and a manufacturing method thereof.

2. Description of the Related Art

In accordance with an increase in energy use, efficient use of limited energy has become an important issue. Particularly, in order to efficiently convert energy into power, a power semiconductor module has been applied in various fields.

Also in the field of inverters, the power semiconductor module has been applied. Particularly, in the field of inverters, since reliability of the power semiconductor module is directly associated with reliability of the inverter, improvements in the reliability of the power semiconductor module as well as improvements in the performance and efficiency of the power semiconductor module have been demanded.

However, in the power semiconductor module, an issue of reliability thereof has not been solved yet.

Particularly, in the case of a wire bonding technology, there is a limitation, in that defects due to a structure required in individually connecting lead frames or lead plates to one another, that is, deteriorations in process properties, erroneous connections, process defects due to a step between power semiconductor devices, and the like, are generated.

In order to cope with this limitation, various wire bonding techniques for increasing a bonding area, as compared to the related art, or utilizing a bonding method different from that of the related art, such as a ribbon bonding method, a frame bonding method, a plate bonding method, and the like, have recently been developed. However, even in the case of the techniques, the issue of reliability described above remains.

The following Related Art Documents, relating to the related art, do not solve the above-mentioned defects.

### RELATED ART DOCUMENT

(Patent Document 1) Korean Patent Laid-Open Publication No. 2010-0008460
(Patent Document 2) Korean Patent Laid-Open Publication No. 2002-0093474

### SUMMARY OF THE INVENTION

An aspect of the present invention provides a power semiconductor module having enhanced reliability and allowing for improvements in process properties and a defect rate by forming an electrical connection using a multilayer substrate having a conductive line provided therein, and a manufacturing method thereof.

According to an aspect of the present invention, there is provided a power semiconductor module including: a lead frame; a base substrate including a circuit wiring formed on an insulating layer thereof; a plurality of power semiconductor devices disposed to contact the circuit wiring; and a multilayer substrate formed by stacking a plurality of substrates and electrically connecting the power semiconductor devices and the lead frame to one another using a connection line formed therein and having conductivity.

The multilayer substrate may include cavities having shapes corresponding to those of the plurality of power semiconductor devices.

The multilayer substrate may include cavities formed therein so as to allow predetermined passive devices to be mounted therein, the passive devices being electrically connected to at least a portion of the plurality of power semiconductor devices through the connection line.

The connection line may include: a first connection line electrically connected to at least a portion of the plurality of power semiconductor devices and allowing gate signals to be input thereto; and a second connection line electrically connecting the plurality of power semiconductor devices to one another.

The connection line may further include a third connection line connecting the circuit wiring and the lead frame to one another.

The connection line may be formed by forming conductive metal patterns on each of the plurality of substrates and stacking the plurality of substrates having the conductive metal patterns formed therein.

The power semiconductor module may further include a control board generating gate signals to control the plurality of power semiconductor devices.

The control board may have one surface electrically connected to the multilayer substrate and the other surface on which control devices are disposed in order to generate the gate signals.

According to another aspect of the present invention, there is provided a manufacturing method of a power semiconductor module, the manufacturing method including: forming an insulating layer and a circuit wiring on one surface of a base substrate; fixing a plurality of power semiconductor devices to the circuit wiring; and forming a multilayer substrate having a connection line formed therein by forming conductive metal patterns or predetermined cavities in each of a plurality of substrates and stacking the plurality of substrates.

The forming of the insulating layer and the circuit wiring may include: depositing a predetermined insulator on the one surface of the base substrate to form the insulating layer; and forming a metal thin film on an upper surface of the insulating layer and then etching the metal thin film to form a pattern.

The forming of the multilayer substrate may include: designing shapes of the cavities in consideration of the power semiconductor devices and the connection line; separately forming the cavities in each of the plurality of substrate according to the designed shapes; and forming vias in each of the plurality of substrates according to the shapes of the cavities.

The forming of the multilayer substrate may include: forming the conductive metal patterns in at least a portion of the vias; and stacking the plurality of substrates to electrically connect the conductive metal patterns to one another, thereby forming the connection line.

The manufacturing method may further include laminating a control board on one surface of the multilayer substrate, the control board controlling the plurality of power semiconductor devices.

The control board may have one surface electrically connected to the multilayer substrate and the other surface on which control devices are disposed in order to generate gate signals.

The manufacturing method may further include forming a housing electrically connecting the connection line of the multilayer substrate to a lead frame and including the power semiconductor module therein.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a general power semiconductor module;

FIG. 2 is a cross-sectional view illustrating a power semiconductor module according to an embodiment of the present invention;

FIG. 3 is a circuit diagram showing a circuit configuration of the power semiconductor module of FIG. 2;

FIG. 4 is a cross-sectional view illustrating a power semiconductor module according to another embodiment of the present invention;

FIG. 5 is a cross-sectional view illustrating a power semiconductor module according to another embodiment of the present invention;

FIG. 6 is a reference diagram illustrating a multilayer substrate according to the embodiment of the present invention; and

FIG. 7 is a flow chart illustrating a manufacturing method of a power semiconductor module according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

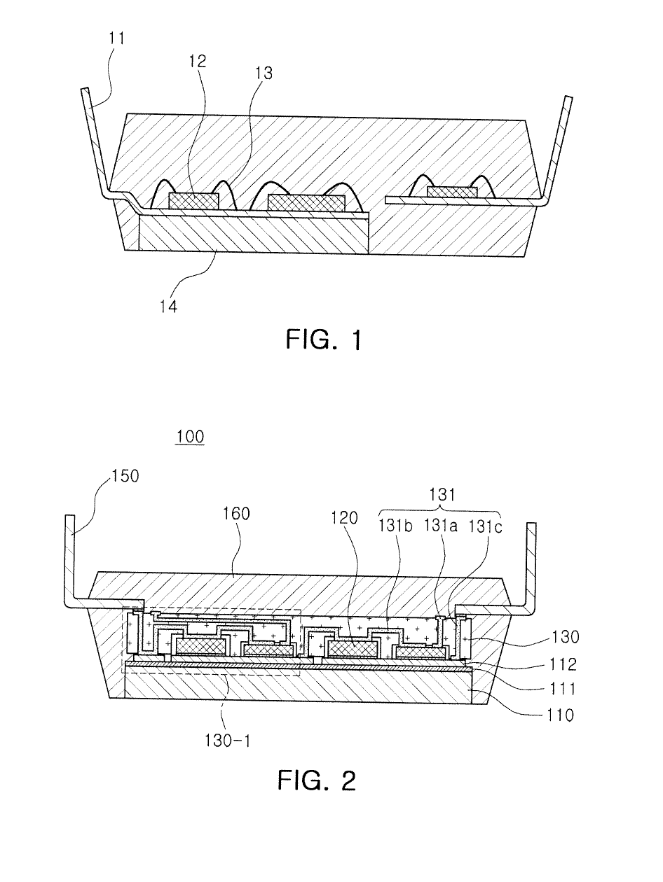

FIG. 1 is a cross-sectional view illustrating a general power semiconductor module.

Referring to FIG. 1, a general power semiconductor module may include a lead frame 11, power semiconductor devices 12, a bonding wire 13, and a base substrate 14.

As shown in FIG. 1, the power semiconductor devices 12 may be connected to wirings of the base substrate 14 through the bonding wire 13. Therefore, accurately connecting the bonding wire 13 and the wirings may be required. However, it is difficult to stably secure reliability in the power semiconductor module due to limitations in wire bonding technology, that is, difficulty in bonding operation and performing accurate bonding, or the like.

In addition, the configuration in which the lead frame 11 includes the power semiconductor devices 12 and the bonding wire 13 is provided. However, even in this configuration, since a volume of the lead frame 11 may be enlarged and a configuration thereof may be complicated, working difficulty may be caused. Further, since wire bonding is performed on the lead frame 11, difficulty in terms of a manufacturing process remains.

FIG. 2 is a cross-sectional view illustrating a power semiconductor module according to an embodiment of the present invention.

Referring to FIG. 2, a power semiconductor module 100 according to the embodiment of the present invention may include a base substrate 110, a plurality of power semiconductor devices 120, a multilayer substrate 130, a lead frame 150, and a housing 160.

The base substrate 110 may have the plurality of power semiconductor devices 120 fixed to one surface thereof. To this end, the base substrate 110 may be provided with a predetermined circuit wiring 112, such that the plurality of power semiconductor devices 120 may be disposed on the circuit wiring.

In the embodiment of the present invention, the base substrate 110 may further include a predetermined insulating layer 111. More specifically, the predetermined insulating layer 111 may be formed on the one surface of the base substrate 110, and the circuit wiring 112 may be formed on one surface of the insulating layer 110 (a surface opposite to a surface thereof toward the base substrate).

The plurality of power semiconductor devices 120 may be disposed to contact the circuit wiring 112. The plurality of power semiconductor devices 120 may be electrically connected to the circuit wiring 112 to configure a power semiconductor circuit.

The multilayer substrate 130 may be formed of a plurality of stacked substrate units. The multilayer substrate 130 may electrically connect the power semiconductor devices 120 to one another using a connection line 131 provided therein and having conductivity. Therefore, the power semiconductor devices 120 may be electrically connected to one another by using the connection line 131 of the multilayer substrate 130 without a separate bonding operation for forming the bonding wire 13 of FIG. 1.

That is, the multilayer substrate 130 may include the connection line 131 provided therein, and the connection line 131 may electrically connect the power semiconductor devices 120 and the lead frame 150 to one another. In addition, the connection line 131 may electrically connect the plurality of power semiconductor devices 120 to one another.

Therefore, the multilayer substrate 130 is used, whereby an electrical connection may be easily undertaken and a reliable connection may be provided.

In the embodiment of the present invention, the connection line 131 may include a first connection line 131a electrically connected to at least a portion of the plurality of power semiconductor devices 120 and allowing gate signals to be input thereto and a second connection line 131b electrically connecting the plurality of power semiconductor devices 120 to one another.

Here, the first connection line 131a may have one end protruding outwardly of the multilayer substrate 130 and the other end exposed to at least a portion of cavities so as to contact a specific power semiconductor device. In addition, in order to electrically connect the plurality of power semiconductor devices 120 to one another, the second connection line 131b may have a distal end exposed to at least a portion of the cavities so as to contact a specific power semiconductor device and or protruding outwardly of the multilayer substrate 130 so as to contact the circuit wiring 112.

In the embodiment of the present invention, the connection line 131 may further include a third connection line 131c connecting the circuit wiring 112 and the lead frame 150 to one another. The lead frame 150 may be a unit electrically connecting the power semiconductor module 100 to the outside. In order to secure a connection area with the outside, the lead frame 150 may be generally manufactured to have a predetermined size or larger. Therefore, the smaller the volume of the lead frame 150 led into the power semiconductor module 100, the more advantageous it is in miniaturizing the power semiconductor module 100. Therefore, the third connection line 131c may be formed in an edge of the circuit wiring 112 to significantly decrease a led portion of the lead frame 150.

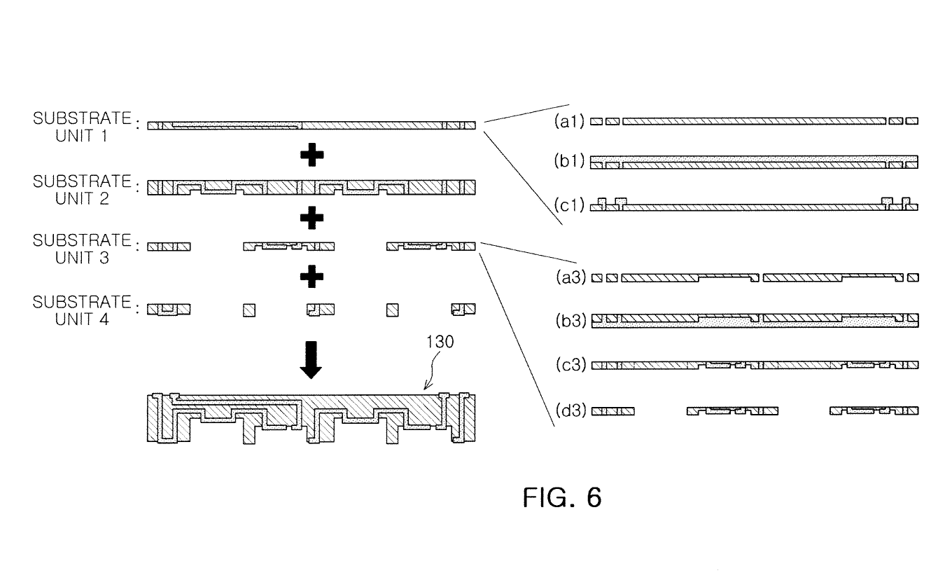

In the embodiment of the present invention, the multilayer substrate 130 may include the cavities having shapes corresponding to those of the plurality of power semiconductor devices 120. That is, the multilayer substrate 130 may include the cavities formed therein in consideration of dispositions and volumes of the plurality of power semiconductor devices 120, and the cavities may include the plurality of power semiconductor devices 120 therein. Therefore, the multilayer substrate 130 may be capped on an upper surface of the base substrate 110 including the power semiconductor devices 120 to enable an electrical connection. The formation of the multilayer substrate will be described below in detail with reference to FIG. 6.

FIG. 3 is a circuit diagram showing a circuit configuration of the power semiconductor module of FIG. 2.

The circuit diagram of FIG. 3 may be configured of the power semiconductor devices 120 and the circuit wiring 112 of FIG. 2. The circuit diagram of FIG. 3 is only an example of a power semiconductor circuit. Therefore, it is obvious that the scope of the present invention is not limited to the circuit diagram of FIG. 3.

A single circuit unit 130-1 of the power semiconductor module in FIG. 3 may be the same as a component denoted by a reference numeral 130-1 of FIG. 2.

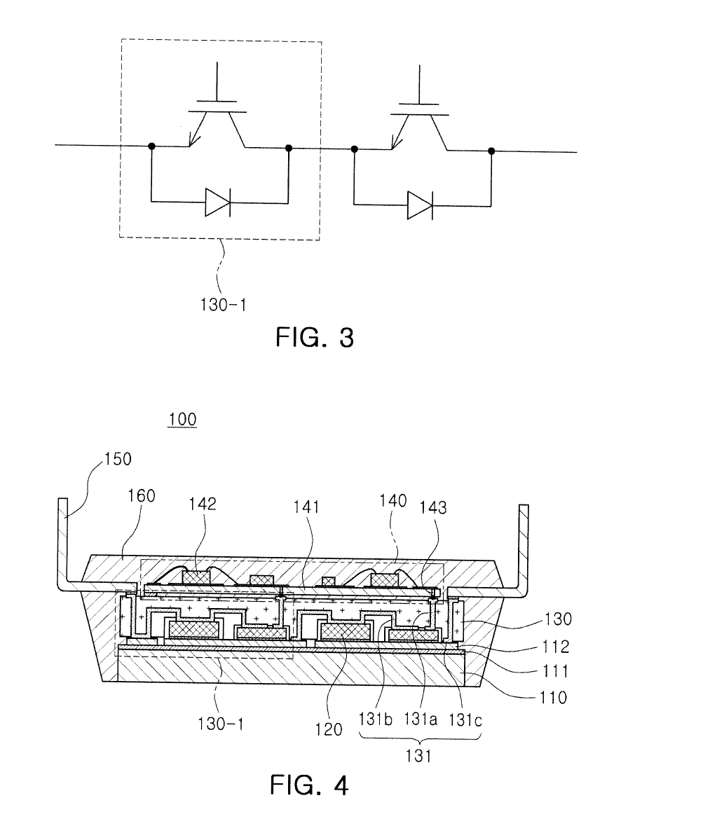

FIG. 4 is a cross-sectional view illustrating a power semiconductor module according to another embodiment of the present invention.

The power semiconductor module according to another embodiment of the present invention shown in FIG. 4 may further include a control board 140 in addition to the components of the power semiconductor module according to the embodiment of the present invention shown in FIG. 2.

The control board 140 may generate gate signals to control the plurality of power semiconductor devices 120. To this end, the control board 140 may have one surface contacting the multilayer substrate 130 and electrically conducted with the multilayer substrate 130 and the other surface on which control devices 142 are disposed in order to generate the gate signals.

In an example shown in FIG. 4, it may be appreciated that the control board 141 has one surface, that is, a lower surface, electrically connected to the connection line 131 of the multilayer substrate 130 through a connecting point 143 and the other surface, that is, an upper surface, of the control board 141 on which the control devices 142 are disposed.

Although the case in which the control devices 142 are coupled to one another by wire bonding is shown in FIG. 4, it is merely provided by way of an example. Therefore, the control devices 142 may also be electrically connected to one another using a multilayer substrate (not shown) for a control board.

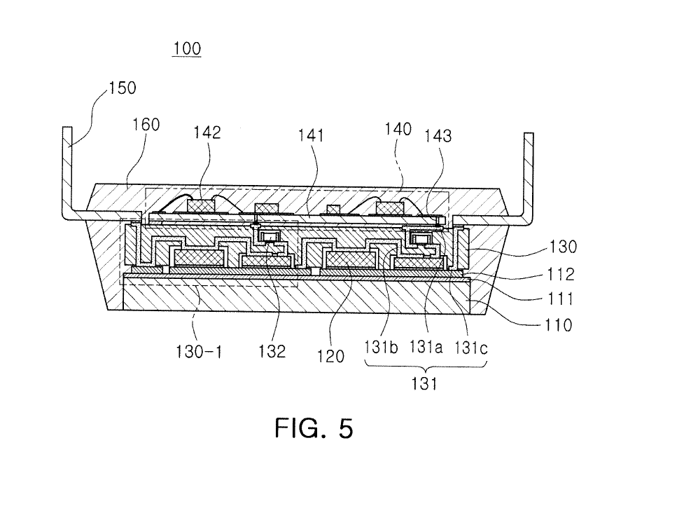

FIG. 5 is a cross-sectional view illustrating a power semiconductor module according to another embodiment of the present invention.

The power semiconductor module according to another embodiment of the present invention shown in FIG. 5 includes passive devices mounted in the multilayer substrate 130.

That is, the multilayer substrate 130 may include the cavities formed therein so as to allow predetermined passive devices 132 to be mounted therein. Here, the passive devices 132 may be electrically connected to at least a portion of the plurality of power semiconductor devices 120 through the connection line 131 to configure a power semiconductor circuit.

Through the embodiment, the passive devices that need to be disposed on the control board 140 may be embedded in the multilayer substrate 130. Therefore, a device mounting area is decreased, whereby the power semiconductor module may be easily miniaturized.

FIG. 6 is a reference diagram illustrating a multilayer substrate according to the embodiment of the present invention.

As shown in FIG. 6, the multilayer substrate 130 may be formed by stacking a plurality of substrate units (substrate unit 1 to substrate unit 4).

More specifically, shapes of the cavities may be designed in consideration of the power semiconductor devices and the connection line. The shapes of the cavities may be separately designed by considering each of the plurality of substrate units (substrate unit 1 to substrate unit 4). Then, according to the separately considered shapes of the cavities, vias may be formed in each of the plurality of substrate units (substrate unit 1 to substrate unit 4) (a1 and a3). Here, the vias refer at least a portion of the cavities formed in the substrate unit. Therefore, the vias may include a via having a wide diameter for forming the cavity in order to contain the power semiconductor device therein as well as a via having a small diameter for forming the connection line 131.

The respective substrate units may form at least a portion of the connection line. To this end, metal thin films may be formed on the substrate units (b1 and b3) and may be etched to form conductive metal patterns (c1 and c3). That is, conductive metal patterns formed on the respective substrate units may be stacked to form the connection line 131.

Then, as needed, the via having a wide diameter for forming the cavity in order to contain the power semiconductor device therein may be formed (d3) to complete the substrate unit.

The plurality of substrate units (substrate unit 1 to substrate unit 4) completed as described above may be sequentially stacked to form the multilayer substrate 130.

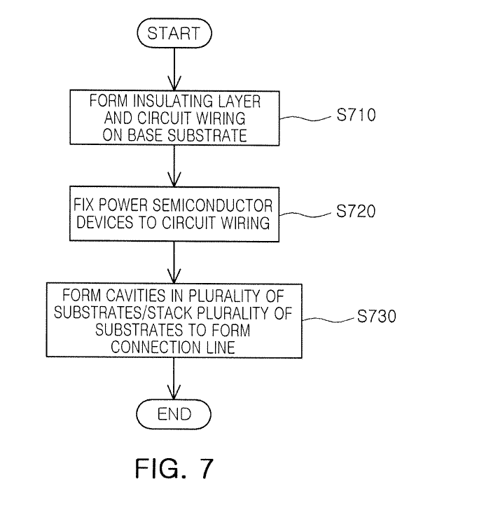

FIG. 7 is a flow chart illustrating a manufacturing method of a power semiconductor module according to an embodiment of the present invention. The manufacturing method of a power semiconductor module according to the embodiment of the present invention shown in FIG. 7 corresponds to a manufacturing method of the power semiconductor module described above with reference to FIGS. 2 through 6. Therefore, a description of the content the same as or corresponding to the above-mentioned content will be omitted. However, with reference to the above-mentioned description, those skilled in the art will understand the manufacturing method of a power semiconductor module according to the embodiment of the present invention to be described below.

Referring to FIG. 7, in the manufacturing method of a power semiconductor module, the insulating layer 111 and the circuit wiring 112 are formed on one surface of the base substrate (S710), and the plurality of power semiconductor devices 120 are fixed to the circuit wiring 112 (S720). Then, conductive metal patterns or predetermined cavities are formed in each of the plurality of substrate units, and the plurality of substrate units are stacked to form the multilayer substrate having the connection line formed therein (S730), thereby manufacturing the power semiconductor module.

In the embodiment of the present invention, the forming (S710) of the insulating layer 111 and the circuit wiring 112 may include depositing a predetermined insulator on the one surface of the base substrate 110 to form the insulating layer 111 and forming a metal thin film on an upper surface of the insulating layer 111 and then etching the metal thin film to form a pattern.

In the embodiment of the present invention, the forming (S730) of the multilayer substrate may include designing shapes of the cavities in consideration of the power semiconductor devices 120 and the connection line 131, separately forming the cavities in each of the plurality of substrate units according to the designed shapes, and forming vias in each of the plurality of substrate units according to the shapes of the cavities.

In the embodiment of the present invention, the forming (S730) of the multilayer substrate may include forming conductive metal patterns in at least a portion of the vias and stacking the plurality of substrate units to electrically connect the conductive metal patterns to one another, thereby forming the connection line.

In the embodiment of the present invention, the manufacturing method of a power semiconductor module may further include laminating the control board on one surface of the multilayer substrate, and the control board may control the plurality of power semiconductor devices. Here, the control board may have one surface electrically conducted with the multilayer substrate and the other surface on which the control devices 142 are disposed in order to generate the gate signals.

In the embodiment of the present invention, the manufacturing method of a power semiconductor module may further include forming the housing 160 electrically connecting the connection line 131 of the multilayer substrate 130 to the lead frame 150 and including the power semiconductor module 100 therein.

As set forth above, according to the embodiment of the present invention, a power semiconductor module having enhanced reliability and allowing for improvements in process properties and a defect rate by forming an electrical connection using a multilayer substrate having a conductive line provided therein, and a manufacturing method thereof can be provided.

While the present invention has been shown and described in connection with the embodiments, it will be apparent to those skilled in the art that modifications and variations can be made without departing from the spirit and scope of the invention as defined by the appended claims.

What is claimed is:

1. A power semiconductor module comprising:
a lead frame;
a base substrate including a circuit wiring formed on an insulating layer thereof;
a plurality of power semiconductor devices disposed to contact the circuit wiring; and
a multilayer substrate formed by stacking a plurality of substrates and electrically connecting the power semiconductor devices and the lead frame to one another using a connection line formed therein and having conductivity.

2. The power semiconductor module of claim 1, wherein the multilayer substrate includes cavities having shapes corresponding to those of the plurality of power semiconductor devices.

3. The power semiconductor module of claim 1, wherein the multilayer substrate includes cavities formed therein so as to allow predetermined passive devices to be mounted therein, the passive devices being electrically connected to at least a portion of the plurality of power semiconductor devices through the connection line.

4. The power semiconductor module of claim 1, wherein the connection line includes:
a first connection line electrically connected to at least a portion of the plurality of power semiconductor devices and allowing gate signals to be input thereto; and
a second connection line electrically connecting the plurality of power semiconductor devices to one another.

5. The power semiconductor module of claim 4, wherein the connection line further includes a third connection line connecting the circuit wiring and the lead frame to one another.

6. The power semiconductor module of claim 1, wherein the connection line is formed by forming conductive metal patterns on each of the plurality of substrates and stacking the plurality of substrates having the conductive metal patterns formed therein.

7. The power semiconductor module of claim 1, further comprising a control board generating gate signals to control the plurality of power semiconductor devices.

8. The power semiconductor module of claim 7, wherein the control board has one surface electrically conducted with the multilayer substrate and the other surface on which control devices are disposed in order to generate the gate signals.

9. A manufacturing method of a power semiconductor module, the manufacturing method comprising:
forming an insulating layer and a circuit wiring on one surface of a base substrate;
fixing a plurality of power semiconductor devices to the circuit wiring; and
forming a multilayer substrate having a connection line formed therein by forming conductive metal patterns or predetermined cavities in each of a plurality of substrates and stacking the plurality of substrates.

10. The manufacturing method of claim 9, wherein the forming of the insulating layer and the circuit wiring includes:
depositing a predetermined insulator on the one surface of the base substrate to form the insulating layer; and
forming a metal thin film on an upper surface of the insulating layer and then etching the metal thin film to form a pattern.

11. The manufacturing method of claim 9, wherein the forming of the multilayer substrate includes:
designing shapes of the cavities in consideration of the power semiconductor devices and the connection line;
separately forming the cavities in each of the plurality of substrate according to the designed shapes; and
forming vias in each of the plurality of substrates according to the shapes of the cavities.

12. The manufacturing method of claim 11, wherein the forming of the multilayer substrate includes:
forming the conductive metal patterns in at least a portion of the vias; and
stacking the plurality of substrates to electrically connect the conductive metal patterns to one another, thereby forming the connection line.

13. The manufacturing method of claim 9, further comprising laminating a control board on one surface of the multilayer substrate, the control board controlling the plurality of power semiconductor devices.

14. The manufacturing method of claim 13, wherein the control board has one surface electrically conducted with the multilayer substrate and the other surface on which control devices are disposed in order to generate gate signals.

15. The manufacturing method of claim 9, further comprising forming a housing electrically connecting the connection line of the multilayer substrate to a lead frame and including the power semiconductor module therein.
